(19) United States
(12) Patent Application Publication
(10) Pub. No.: US 2026/0045922 A1
(43) Pub. Date: Feb. 12, 2026

(54) COMMON MODE COMPENSATION CIRCUIT FOR DIFFERENTIAL AMPLIFIERS, CORRESPONDING DEVICE AND METHOD

(71) Applicant: STMicroelectronics International N.V., Geneva (CH)

(72) Inventors: Roberto MODAFFARI, Domodossola (IT); Paolo PESENTI, Senago (IT)

(73) Assignee: STMicroelectronics International N.V., Geneva (CH)

(21) Appl. No.: 19/289,497

(22) Filed: Aug. 4, 2025

(30) Foreign Application Priority Data
Aug. 6, 2024 (IT) 102024000018490

(51) Int. Cl. H03F 3/45

(52) U.S. Cl. CPC H03F 3/45179; H03F 2203/45116

(57) ABSTRACT

A differential input stage includes first and second input transistors with current flow paths are coupled between a tail transistor current flow path and first and second nodes, respectively. An output stage includes first and second output transistors having current flow paths between a supply line and first and second output nodes, respectively, coupled to the first and second nodes. First and second common-mode control transistors have current flow paths jointly coupled to a ground current flow path of a common-mode tail transistor. The first common-mode control transistor has a control terminal resistively coupled to the first and second output nodes. A bias duplicate transistor has a current flow path arranged in a bias current flow line between the supply line and ground. The bias duplicate transistor is coupled in a 1:N current mirror arrangement with the tail transistor in the differential input stage.

### PRIORITY CLAIM

This application claims the priority benefit of Italian Application for Patent No. 102024000018490, filed on Aug. 6, 2024, the content of which is hereby incorporated by reference in its entirety to the maximum extent allowable by law.

### TECHNICAL FIELD

The description relates to common mode compensation circuits for differential amplifiers.

Aspects of the present description can be used in a variety of devices using operational transconductance amplifiers (OTAs). Examples of such devices include: smartphones, smartwatches, tablets and other devices using micro-electromechanical systems (MEMS).

### BACKGROUND

Using certain types of transistors operating at (very) low voltages in operational amplifiers may result in a poor common-mode-rejection-ratio (CMRR). This may lead to a common-mode current undesirably injected at the outputs of the first stage of the amplifier that cannot be suppressed and causes unacceptable instability of the amplifier. This is due to a value of output resistance that is too low and is thus unable to suppress that current.

This issue can be attempted to be addressed using a resistance connected in series to the Miller capacitance (the plain capacitance among nodes in a circuit augmented in the presence of voltage amplification). This is known to increase the phase margin, but also has an impact on the differential feedback of the amplifier.

Increasing the area of the input differential pair of the amplifier may help in “pushing” the input MOSFET transistors in a subthreshold condition and increasing the room available for the tail generator. However, this approach results in a (very) poor efficiency with the risk of leading to an area undesirably expanded (“area explosion”), this being particularly the case if the supply voltage VDD is low (for example, 1.1V or lower).

It is otherwise noted that operational amplifiers such as OTAs are the subject matter of extensive patent literature as witnessed, merely by way of example, by: United States Patent Application Publication Nos. 2003/0112543 A1, 2005/0242874 A1, 2015/0200635 A1, 2015/0200648 A1, 2017/0026007 A1, 2020/0057484 A1, and 2024/0030934 A1, and U.S. Pat. Nos. 4,441,080 A, 4,593,252 A, 6,222,418 B1, and 8,354,887 B1 (all of which are incorporated herein by reference).

Other references of interest include:

U.S. Pat. No. 5,541,555 A (incorporated by reference) which discloses a high-performance operational transconductance amplifier monolithically integrable with CMOS technology comprising a differential input stage connected to a pair of cascode stages and a differential output stage. The output stage comprises two output transistors whose gate terminals are connected to nodes for connection of the input stage and the cascode stages. The output terminals of the amplifier are connected to intermediate nodes of the cascode stages through capacitors.

U.S. Pat. No. 6,407,636 B1 (incorporated by reference) which discloses an operational amplifier that includes an input transconductor stage with differential inputs and an output, an output stage, and at least one intermediate stage connected between the input stage and the output stage so as to form an amplifier chain. The intermediate stage includes a common-emitter bipolar transistor between first and second power supply terminals, and at least one feedback resistor connected between the bipolar transistor emitter and one of the power supply terminals. The intermediate stage also includes at least one feedback capacitance connected between the emitter terminal of the transistor and an output of a next stage.

U.S. Pat. No. 10,171,003 B1 (incorporated by reference) which discloses a method and a controller for controlling a converter wherein a capacitance is charged simultaneously using a first current and a second current that is different from the first current or discharged simultaneously using the first current and the second current. Sourcing and sinking transistors source or sink the first current for charging or discharging the capacitance. An operational transconductance amplifier determines a level of the second current based on a level of current flowing through the resonant tank. The operational transconductance amplifier sources or sinks the second current for charging or discharging the capacitance. Further, logic is provided to output a switching signal for operating the converter based on a voltage across the capacitance.

United States Patent Application Publication No. 2021/0270909 A1 (incorporated by reference) discloses a voltage comparator with an output, a first input and a second input, the first input being coupled to a first reference voltage terminal. An operational transconductance amplifier has an output coupled to the second input of the voltage comparator, an inverting input coupled to the output of the operational transconductance amplifier, and a non-inverting input coupled to a second reference voltage terminal. A filter capacitor is coupled in series between a power supply terminal and the second input of the voltage comparator.

United States Patent Application Publication Nos. 2012/0326790 A1, 2020/0244239 A1, 2021/0408970 A1, 2022/0399863 A1, and 2023/0013952 A1 (all of which are incorporated herein by reference) are further documents of interest.

There is a need in the art to contribute in addressing the issues discussed in the foregoing.

### SUMMARY

One or more embodiments concern a circuit.

Devices using operational transconductance amplifiers (OTAs) such as smartphones, a smartwatches, tablets and/or devices using micro-electromechanical systems (MEMS) are non-limiting examples of devices where solutions described herein can be applied.

A capacitive sensor may represent and advantageous application of such a circuit.

One or more embodiments may concern a corresponding method.

In certain solutions described herein, a capacitive coupling is introduced between a tail node and a bias compensation node to improve the stability of common-mode feedback without any impact on the differential loop.

Such an approach effectively addresses a challenge in low-voltage analog design, particularly in the context of multi-stage OTAs used in fully differential amplifiers, and facilitates achieving stability of the output common-mode feedback network (OCMFB) of an OTA operating at low supply voltages (around 1V or lower).

As noted, the common-mode rejection ratio (CMRR) of the OTA can be compromised due to a reduced output resistance of the tail current source transistor of the amplifier, particularly under certain process, voltage, and temperature (PVT) conditions, with an ensuing instability in the OCMFB loop.

In various solutions described herein, an additional network such as a resistor capacitor (RC) network can be provided in order to improve the stability of the OCMFB by effectively restoring the CMRR for frequencies near the 0 dB crossing of the OCMFB loop. Providing such an RC network may involve duplicating a biasing network of the tail current source and adding a compensation path with a capacitor and a resistor.

This network can effectively cancel out the undesired common-mode current caused by perturbations in the common-mode voltage, thereby reducing the common-mode gain (GCM) of the OTA and improving stability. This may involve introducing transistors to duplicate the network that generates the bias point of the tail current source.

In various solutions described herein, the added compensation path (including an RC network of a capacitor and a resistor or other possible implementations) propagates common-mode perturbations to the gate of a transistor, which in turn generates a signal that facilitates current mirroring and cancellation.

A compensation current based on that signal is read by a transistor and mirrored into the tail current source. Judicious sizing of these components facilitates AC cancellation of the common-mode current, reducing the common-mode gain of the OTA. The addition of the compensation network results in a significant improvement in the phase margin and transient response of the OCMFB.

Implementations of solutions described herein may dispense with such an RC network and are not limited to AC cancellation of the common-mode current and can thus facilitate also DC cancellation of the common-mode current.

Improvements resulting from solutions described herein can be observed across different PVT corners, including the challenging corner currently referred to as the SSA −40° C. corner.

Results obtained for solutions described herein indicate a better phase margin and reduced ringing in the transient response when the compensation network is implemented.

Comparing performance of an OTA including a compensation network as described herein with performance of an OTA that does not include such a compensation network demonstrates the efficacy of the compensation network in enhancing stability across different temperature corners in addressing the stability issues that arise in low-voltage multistage OTAs.

Such a compensation network was found to mitigate the negative impact of a low output resistance in the tail current source under low supply voltage conditions. This facilitates maintaining adequate performance and reliability of an OTA which in turn facilitates integrating analog circuitry with digital functions in modern low-power applications.

### BRIEF DESCRIPTION OF THE DRAWINGS

One or more embodiments will now be described, by way of example only, with reference to the annexed figures, wherein:

FIG. 1 is a diagram illustrative of architecture of a fully differential amplifier;

FIG. 2 is a diagram illustrative of an equivalent common-mode model of the fully differential amplifier of FIG. 1 implemented using a 2-stage fully differential amplifier;

FIG. 3 is a diagram illustrative of an equivalent common-mode model of the fully differential amplifier of FIG. 1 implemented using a 3-stage fully differential amplifier;

FIG. 4 is a circuit diagram of a possible implementation of a 2^{nd} order operational transconductance amplifier;

FIG. 5 illustrates the possible presence of an undesired positive common-mode loop in amplifier architecture as illustrated in FIG. 1;

FIG. 6 illustrates the possible presence of such a positive common-mode loop within the framework of an equivalent common-mode model;

FIGS. 7 and 8 illustrate, still within the framework of an equivalent common-mode model, the possible application of a general concept underlying solutions as proposed herein;

FIG. 9 exemplifies a first possible implementation of that concept in an amplifier circuit;

FIG. 10A illustrates a 2-stage operational transconductance amplifier (OTA) structure showing a possible arrangement of transistors according to solutions as described herein;

FIG. 10B is a corresponding common-mode model for architecture illustrated in FIG. 10A;

FIGS. 11A and 12A exemplify possible circuit implementations of solutions as described herein; and

FIGS. 11B and 12B illustrate respective equivalent common-mode models for architectures as illustrated in FIGS. 11A and 12A.

### DETAILED DESCRIPTION

The figures are drawn to clearly illustrate the relevant aspects of the embodiments and are not necessarily drawn to scale. The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

For the sake of simplicity and ease of explanation: a same designation may be applied throughout this description to designate a certain node or line as well as a signal occurring at that node or line (the supply line or node referred to in the following as VDD may be exemplary of this); a same designation may be applied throughout this description to designate certain component (such as a capacitor, resistor or inductor) as well as electrical parameters thereof.

Also, when it is mentioned that an element is “connected to” or “coupled to” another element, it should be understood that still another element may be interposed therebetween, as well as that the element may be connected or coupled directly to another element.

On the contrary, when it is mentioned that an element is “connected directly to” or “coupled directly to” another element, it should be understood that still another element is not interposed therebetween.

Low-voltage analog design is a current market trend that is essentially driven by the desire of integrating complex digital functions (that involve scaled technology nodes typically supplied with supply voltages VDD in the order of 1.2V or lower) with analog circuitry that should desirably maintain good performance and reliability despite a reduction in the supply voltage.

A point to take into account when considering a reduction in the supply voltage of an analog domain is related to the topology of the amplifiers involved.

An established concept with those skilled in the art is that, in the presence of a given supply voltage VDD, a multistage operational amplifier facilitates achieving a signal voltage swing that is higher than the signal voltage swing that can be reached with single-stage OTAs.

Multistage OTAs thus represent a current approach adopted by circuit designers when faced with the problem of reducing a supply voltage while maintaining a desired signal-to noise ratio (SNR) of a given application.

As already noted, various issues may arise in connection with the prospected use of low-voltage multistage OTAs.

One such issue is related to the stability of the common-mode feedback loop for operational amplifiers expected to operate with supply voltages in the range of 1V or lower.

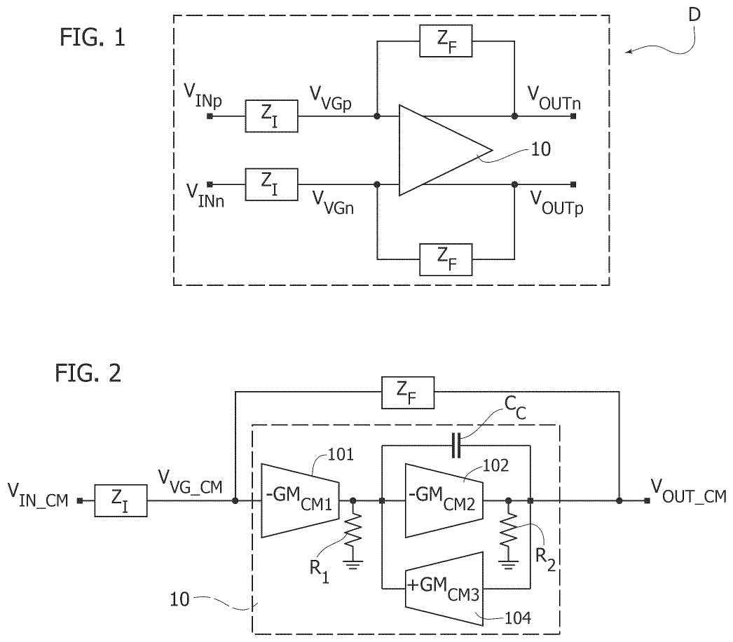

FIG. 1 represents architecture of fully differential amplifier circuitry built around an operational transconductance amplifier (hereinafter, briefly OTA) 10. Such a transconductance amplifier can be advantageously incorporated in a capacitive sensor.

Whatever the specific application envisaged, this kind of amplifier 10 has: two input nodes to the OTA 10, namely V_{VGp}, V_{VGn}, each having applied an input (voltage) signal V_{INp}, V_{INn} via an input network Z_{I}; and output nodes from the OTA 10, namely V_{OUTn}, V_{OUTp}, each coupled to a respective input node V_{VGp}, V_{VGn} to the OTA 10 via a feedback network Z_{F} so that a (negative) differential feedback is returned to the input according to a desired function to the block.

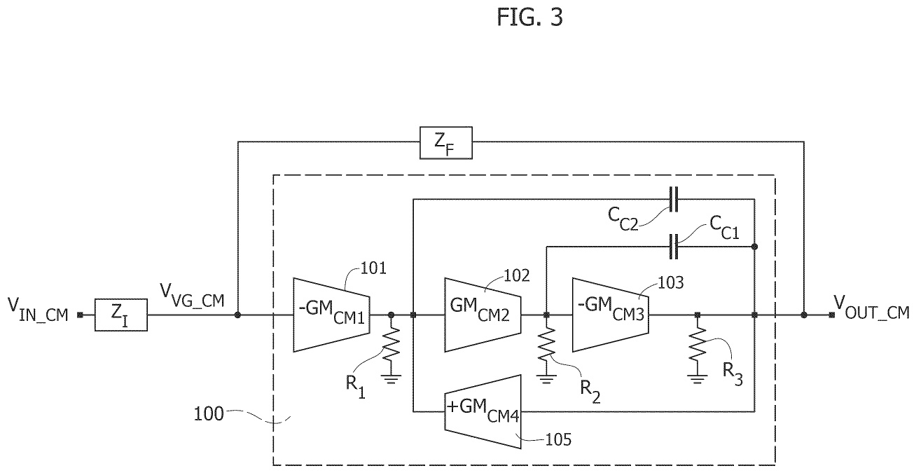

FIG. 2 is a diagram illustrative of the equivalent common-mode model of a fully differential amplifier implemented using a 2-stage OTA where single blocks designated Z_{I} and Z_{F} are shown under the (reasonable) assumption that the corresponding networks in the differential architecture of FIG. 1 have the same values.

In the case of the equivalent common-mode model of FIG. 2: GM_{CM1} (block 101) is the common-mode transconductance of the first stage of the OTA 10; R₁ is the common-mode output resistance of the first stage of the OTA 10; GM_{CM2} (block 102) is the common-mode transconductance of the second stage of the OTA; R₂ is the common-mode output resistance of the second stage of the OTA; GM_{CM4} (block 104) is the transconductance of the common-mode control-stage of the OTA; and C_{C} is a capacitance which can be regarded as arranged across the second stage 102 and the common-mode control-stage 104 of the OTA.

In the case of the equivalent common-mode model of FIG. 2 the following relationships apply:

$${V}_{IN \_ CM} = ( {V}_{INp} + {V}_{INn} ) / 2$$

$${V}_{VG \_ CM} = ( {V}_{VGp} + {V}_{VGn} ) / 2$$

$${V}_{OUT \_ CM} = ( {V}_{OUTp} + {V}_{OUTn} ) / 2 .$$

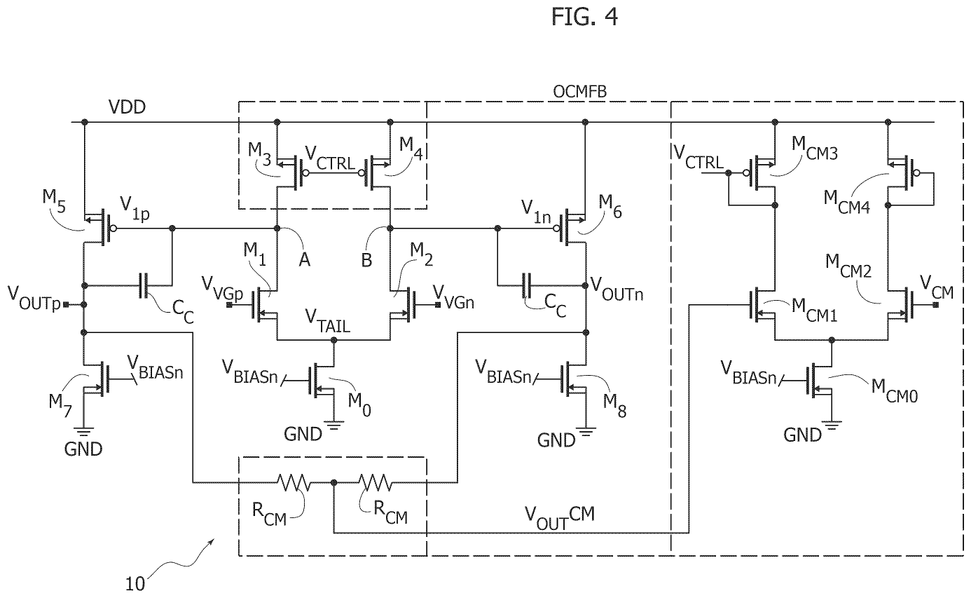

FIG. 3 is a diagram illustrative of the equivalent common-mode model of a 3-stage OTA. Here again, single blocks designated Z_{I} and Z_{F} are shown under the assumption that the corresponding networks in the differential architecture of FIG. 1 have the same values.

In the case of the equivalent common-mode model of FIG. 3: GM_{CM1} (block 101) is the common-mode transconductance of the first stage of the OTA 10; R₁ is the common-mode output resistance of the first stage of the OTA 10; GM_{CM2} (block 102) is the common-mode transconductance of the second stage of the OTA; R₂ is the common-mode output resistance of the second stage of the OTA; GM_{CM3} (block 103) is the common-mode transconductance of the third stage of the OTA; R₃ is the common-mode output resistance of the third stage of the OTA; GM_{CM5} (block 105) is the transconductance of the common-mode control-stage of the OTA; C_{C1} is a capacitance which can be regarded as arranged across in parallel to the third stage 103 of the OTA; and C_{C2} is a capacitance which can be regarded as arranged across the cascade of the second stage 102 and the third stage 103 of the OTA.

The representations of FIG. 2 and FIG. 3 are intended to highlight the fact that the issues discussed in the foregoing (and the solutions described herein as well) apply to differential amplifiers such as OTAs irrespective to the number of stages therein.

As noted, multistage OTAs facilitate achieving a higher output voltage swing for a given supply voltage. This suggests using multistage OTAs in case of low-voltage operation (that is with a supply voltage VDD in the range of 1V or lower).

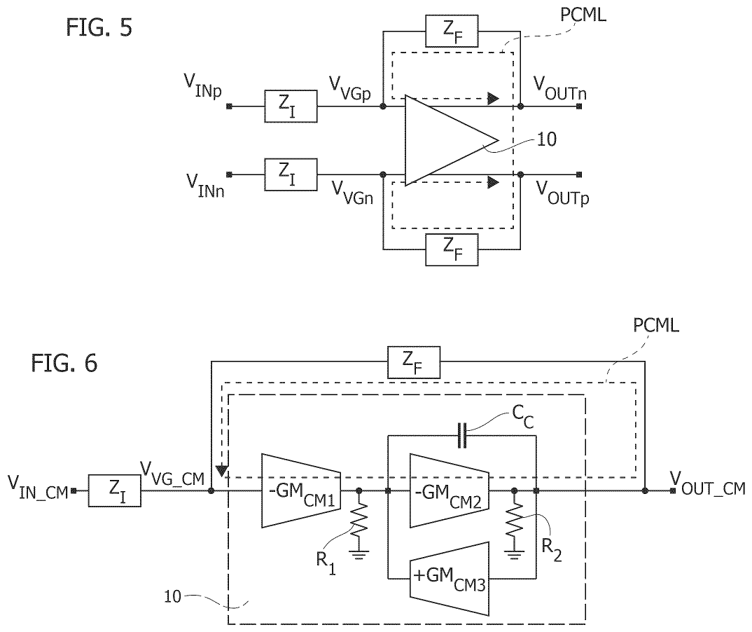

FIG. 4 is circuit diagram of a 2^{nd} order OTA.

As illustrated in FIG. 4, an exemplary OTA is intended to operate between a supply node or line at a voltage VDD and ground GND, with a differential input signal V_{VGp}, V_{VGn} applied at an input stage between the control terminals (gates, in the case of field-effect transistors such as MOSFET transistors) of a first transistor M₁ and a second transistor M₂ having the current flow-paths therethrough (source-drain, in the case of field-effect transistors such as MOSFET transistors) coupled to the line/node VDD via the (source-drain) current flow-paths through a third transistor M₃ and a fourth transistor M₄, respectively.

The third transistor M₃ and the fourth transistor M₄ have their control terminals (gates, in the case of field-effect transistors such as MOSFET transistors) mutually coupled via a line V_{CTRL}.

The source-drain current flow paths through the first transistor M₁ and the second transistor M₂ join at their ends opposite the transistors M₃ and M₄ at a line V_{TAIL} that is coupled to ground GND via the source-drain current flow-path through a tail transistor M₀.

The figures and the relative description are illustrative of a field-effect transistor (MOSFET) implementation of the various circuits discussed.

In fact, solutions as described herein can be advantageously used in connection with MOSFET transistors such as PMOS transistors (see, for instance, the transistors M_{C}, MD₁, M_{E} and M₀ discussed in the following).

At least in principle, at least some of the field-effect transistors described herein could be replaced by bipolar junction transistor (BJT), where the control terminals will be the bases of these transistors and the current paths therethrough will be represented by the emitter-collector current flow path.

Likewise, the figures and the relative description are illustrative of implementations where VDD is assumed to be a positive voltage with respect to ground GND, with the polarities of the transistors (p-channel/n-channel and p-n-p/n-p-n) selected correspondingly. Those of skill in the art can easily devise corresponding adaptations in case of different voltage/polarity options.

At a node designated A, located between the transistors M₁ and M₃, a voltage V₁ₚ is applied to the control terminal (gate in the case of a field-effect transistors such as a MOSFET transistor) of a transistor M₅ having the source-drain current flow-path therethrough cascaded with the source-drain current flow-path through a transistor M₇ in a current flow line between the supply node or line VDD and ground GND with an output voltage V_{OUTp} provided at a node intermediate the transistors M₅ and M₇, with such an intermediate node coupled to the node A via a capacitance C_{C} (see also FIG. 2).

At a node designated B, located between the transistors M₂ and M₄, a voltage V₁ₙ is applied to the control terminal (gate in the case of a field-effect transistors such as a MOSFET transistor) of a transistor M₆ having the source-drain current flow-path therethrough cascaded with the source-drain current flow-path through a transistor M₈ in a current flow line between the supply node or line VDD and ground GND with an output voltage V_{OUTn} provided at a node intermediate the transistors M₆ and M₈ such as the intermediate node coupled to the node B via a capacitance C_{C} (see again FIG. 2).

The difference between the voltages V_{OUTp} and V_{OUTn} provides a (differential) output from the OTA 10.

The output nodes V_{OUTp} and V_{OUTn} can be regarded as being coupled via respective output resistances R_{CM} to a “common-mode” output line V_{OUT}CM towards the control terminal (gate in the case of a field-effect transistor such as a MOSFET transistor) of a transistor M_{CM1} having the source-drain current flow-path therethrough cascaded with the source-drain current flow-path through a diode-connected transistor M_{CM3} arranged between the transistor M_{CM1} and the supply node/line VDD. The transistor M_{CM3} has its control terminal (gate, in the case of a field-effect transistor such as a MOSFET transistor) and the current flow-path therethrough (and its drain, in the case of a field-effect transistor such as a MOSFET transistor) connected to the line named V_{CTRL} between the gates of the transistors M₃ and M₄.

A “common-mode” signal V_{CM} (generated in a manner known per se to those of skill in the art) is applied to the control terminal (gate, in the case of a field-effect transistor such as a MOSFET transistor) of a transistor M_{CM2} having the source-drain current flow-path therethrough cascaded with the source-drain current flow-path through a diode-connected transistor M_{CM4} arranged between the transistor M_{CM2} and the supply node/line VDD.

The source-drain current flow paths through the transistor M_{CM1} and the transistor M_{CM2} join at their ends opposite the transistors M_{CM3} and M_{CM4} at the source-drain current flow-path through a tail transistor MCMO.

The control terminals (gates in the case of field-effect transistors such MOSFET transistors) of the transistors M₀, M₇, M₈, and M_{CM0} have applied thereto a bias voltage V_{BIASn} (generated in a manner known per se to those of skill in the art).

The circuit diagram of FIG. 4 highlights the presence of a common-mode feedback network (OCMFB) from the output nodes V_{OUTp}, V_{OUTn} towards the nodes A, B (and thus the nodes V_{VGp}, V_{VGn}) via the resistors R_{CM} and the line V_{OUT}CM.

As otherwise known to those skilled in the art, the OCMFB working principle involves reading an output common-mode voltage of the OTA defined as:

$${V}_{OUT} CM = ( {V}_{OUTp} + {V}_{OUTn} ) / 2$$

using the resistances R_{CM}, and comparing this signal with a reference voltage V_{CM} using a differential pair represented by the common-mode control transistors M_{CM1} and M_{CM2}. The error signal generated by this differential pair is mirrored to the active load of the operational amplifier (transistors M₃ and M₄) with the aim of obtaining an output common-mode voltage V_{OUT}CM that matches the signal V_{CM}.

This common-mode voltage is usually defined at system level and determines also the DC potential of the virtual ground (nodes V_{VGp} and V_{VGn} in FIGS. 1 and 4) of the analog block that uses the OTA.

A value for signal V_{CM} can be selected as V_{CM}=VDD/2 as this may maximize the output swing of the stages.

By way of possible numerical example, one may consider VDD=1.2V and V_{CM}=0.6V, which is the same for V_{VGp} and V_{VGn} in FIG. 2.

This means that the gate-to-source voltage V_{GS} of the input differential pair including the transistors M₁ and M₂ must be accommodated in such a small range of 0.6V while leaving enough room for the current generator (transistor M₀) to preserve an acceptable output resistance rₒᵤₜM₀ for that current generator.

In practice, this will result in operation of the input transistors M₁ and M₂ in a deep subthreshold region, also with the transistor M₀ biased in this region, in so far as the parameter V_{DS_SAT} (drain-to-source saturation voltage) is reduced, thus facilitating preserving an “acceptable” output resistance.

The area of the differential pair (transistors M₁ and M₂) and the current generator transistor M₀ may be attempted to be selected with the aim of reducing the V_{GS} voltages and the saturation voltage V_{DS_SAT}.

It is otherwise observed that, in the presence of a low value of the supply voltage VDD, there will be PVT (Process-Voltage-Temperature) corners where the output resistance of transistor M₀ will drop, with a detrimental effect on the common-mode-rejection-ratio (CMRR) of the operational amplifier.

In these corners the OCMFB can potentially became unstable.

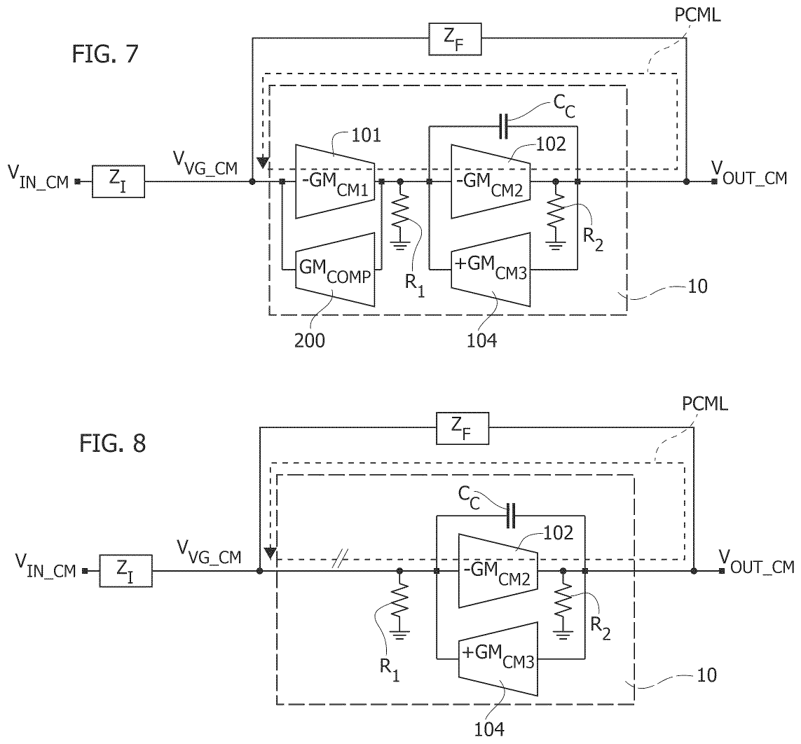

As schematically represented in FIG. 5 (by direct comparison with FIG. 1) this instability is related to a positive common-mode loop PCML expressed by the multistage OTA 10 in response to a reduction of the output resistance r_{OUT}M₀ at tail generator transistor M₀.

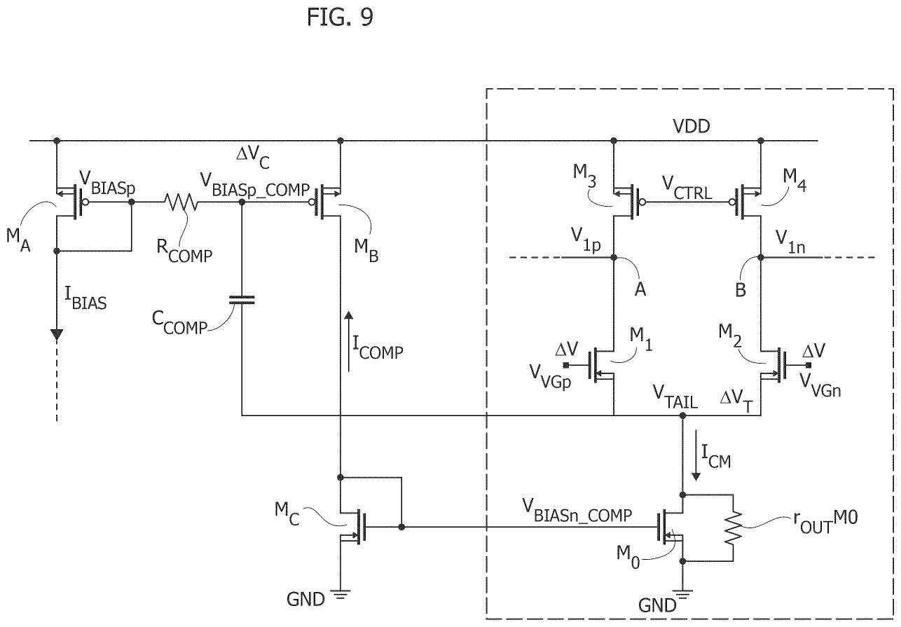

This positive common-mode loop is also represented in FIG. 6 by referring to the common-mode model of FIG. 2.

In FIGS. 5 and 6 (where the undesired positive common-mode loop PCML is highlighted) parts/elements/entities already introduced in connection with FIGS. 1 and 2 are indicated with the same reference symbols and a corresponding description will not be repeated here for brevity.

It is observed that, for a given application, the output common-mode is brought back to the inputs through the specific feedback network of the block, and it is then amplified by the common-mode gain of the OTA defined as:

$${G}_{CM} = ( {V}_{OUTp} + {V}_{OUTn} ) / ( {V}_{INp} + {V}_{INn} ) .$$

This common-mode loop PCML as represented in FIGS. 5 and 6 (with positive gain for multistage OTAs, and negative gain for single-stage OTAs) works together with the internal OCMFB of the OTA modifying its properties.

In a typical corner, the effect of this undesired additive loop may be limited by the CMRR of the OTA 10 that reduce the value of G_{CM}, but on some PVT corner where the CMRR drops (usually at cold temperature), the interaction of the two loops PCML could lead to instability.

The stability of an OCMFB loop in a 2-stage OTA can be investigated by noting that, for instance, while a TYP 27° C. corner can be tolerated (no instability) for a certain OTA, stability is severely deteriorated at the SSA −40° C. corner, as expressed by both a poor phase margin PM (with PM=35° in SSA −40° C. in comparison to PM=52° in TYP 27° C.) of the Bode plot and a resulting ringing noticeable in transient simulation.

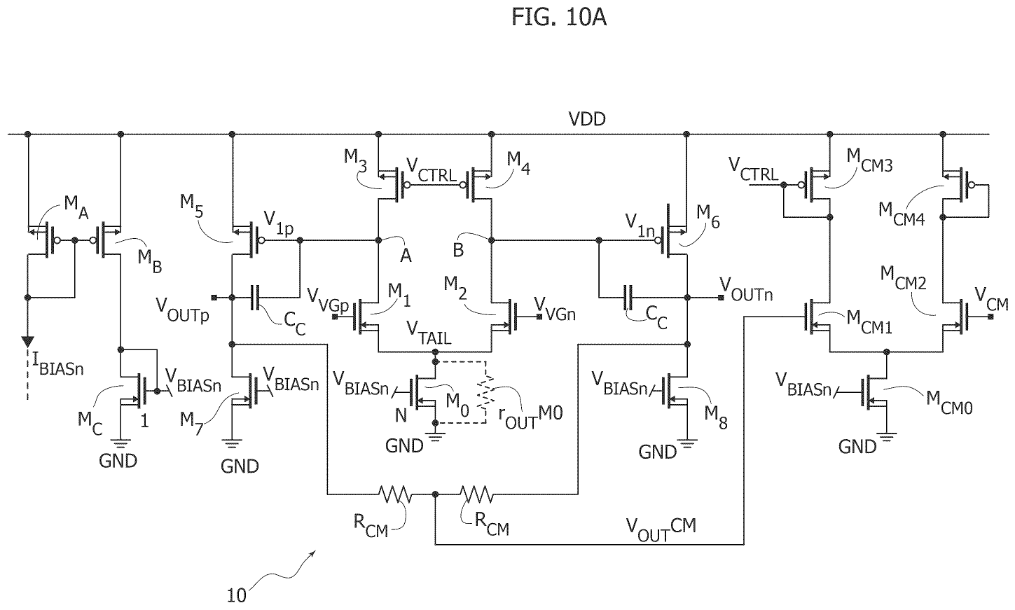

Solutions as proposed herein are represented in FIGS. 7 and 8 by referring at first to an equivalent common-mode model as already introduced in connection with FIG. 2 and FIG. 6.

In FIGS. 7 and 8 parts/elements/entities already introduced in connection with FIGS. 2 and 6 are indicated with the same reference symbols and a corresponding description will not be repeated here for brevity.

Essentially, a first possible implementation of solutions as proposed herein can be based on the introduction of a resistor capacitor (RC) network (essentially the block GM_{COMP} indicated as 200 in FIG. 7) with the purpose of partially restoring the CMRR of the OTA at least for the range of frequency near the 0 dB crossing of the OCMFB.

By introducing the block/stage 200 with GM_{COMP}=GM_{CM1} (block 101) the undesired positive common-mode loop PCML is removed.

Stated otherwise (and as depicted in FIG. 8), under the condition GM_{COMP}=GM_{CM1}, the CMRR of the OTA is virtually infinite with the possibility of effectively reducing extra noise/area/current consumption.

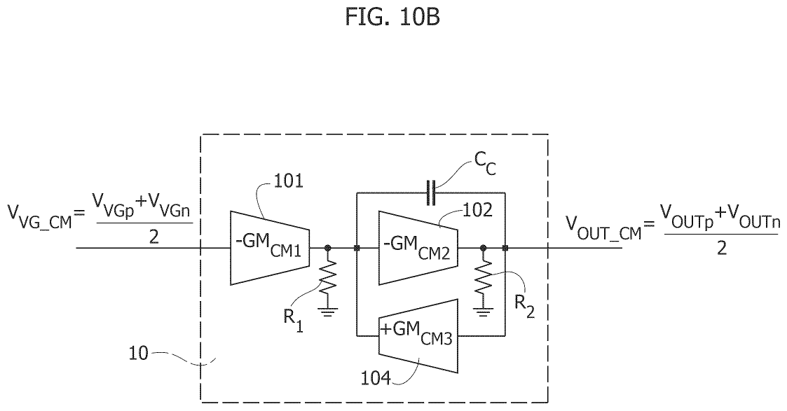

FIG. 9 is a first example of a possible circuit implementation of a solution as proposed herein.

It is again recalled that solutions as proposed herein can be advantageously used in connection with “small” supply voltages VDD (1.1 V or lower).

In FIG. 9, the first stage of the OTA of FIG. 4 including the transistors M₀, M₁, M₂, M₃ and M₄ is reproduced (a detailed description is not repeated for brevity) by highlighting the output resistance rₒᵤₜM₀ of the “tail” transistor M₀ traversed by a current IC_{M}.

It is noted that, while represented as a distinct component for clarity of illustration, the resistance rₒᵤₜM₀ is in fact an intrinsic parameter of the source-drain current flow path through the transistor M₀.

The network associated to the first stage of the OTA illustrated in FIG. 9 includes three transistors M_{A}, M_{B}, M_{C} (MOSFET transistors for instance).

The (diode-connected) transistor M_{A} and the transistor M_{B} have their control terminals (gates, in the case of field-effect transistors such as MOSFET transistors) coupled via a resistor R_{COMP} with a capacitor C_{COMP} having a first end connected to a node between the resistor R_{COMP} and the gate of the transistor M_{B} and a second end connected to the line V_{TAIL} between the tail transistor M₀ and the mutually connected current flow paths through the transistors M₁ and M₂.

Both transistors M_{A} and the transistor M_{B} have the current flow-paths therethrough coupled (at their sources, for instance) to the supply line/node VDD.

The (diode-connected) transistor M_{A} (whose control terminal coupled to the resistor R_{COMP} is at a voltage V_{BIASp}) has a bias current I_{BIAS} flowing therethrough (generated in a manner known per se to those skilled in the art) that serves as a reference current of the circuit.

The transistor M_{B} (whose control terminal coupled to the resistor R_{COMP} is at a voltage V_{BIASp_COMP}) has a current flow path therethrough cascaded with the current flow path through the (diode connected) transistor M_{C}.

The (diode connected) transistor M_{C} is arranged between the transistor M_{B} and ground GND and has its control terminal (gate, in the case of a field-effect transistor such as a MOSFET transistor) coupled in a current-mirror arrangement to the control terminal of the tail transistor M₀ via a line at a voltage V_{BIASn_COMP}.

The action of the network associated to the first stage of the OTA as illustrated in FIG. 9 in improving the stability of the OCMFB can be explained by considering a common-mode perturbation taking place on the outputs of the amplifier.

Such a perturbation (labeled ΔV in FIG. 9) is brought to the inputs V_{VGp} and V_{VGn} of the OTA through the feedback network (Z_{F} in FIG. 5, for immediate reference).

This perturbation results in a common-mode current IC_{M}:

$${I}_{CM} = Δ {V}_{T} / {r}_{OUT} {M}_{0}$$

where ΔV_{T} is the amplitude of the common-mode perturbation that actually reaches the node V_{TAIL} of the OTA and r_{OUT}M₀ is the output resistance of the transistor M₀.

As discussed, this undesired current should be kept as low as possible, which may not be feasible due to the detrimental effect that low-voltage designs have on the resistance r_{OUT}M₀, especially at PVT corners.

The circuit of FIG. 9 is exemplary of the possibility of duplicating the network that generates the bias point of the tail current generator M₀ (via the transistors M_{A}, M_{B} and M_{C}) and with the C-R path represented by the capacitance C_{COMP} and the resistance R_{COMP}.

With this path, the perturbation ΔV_{T} is propagated to (the gate of) the transistor M_{B} that generates the signal ΔV_{C}, and the consequent current I_{COMP} read from the transistor M_{C} and mirrored into the transistor M₀.

In response to a judicious sizing of the components R_{COMP}, C_{COMP} and M_{B}, the current I_{COMP} gives in return an AC cancellation of the current IC_{M} thus reducing, in AC operation, the common-mode gain G_{CM} of the operational amplifier.

This was found to result in a marked improvement of the OCMFB phase margin and transient response both in the corners TYP 27° C. and SSA −40° C.

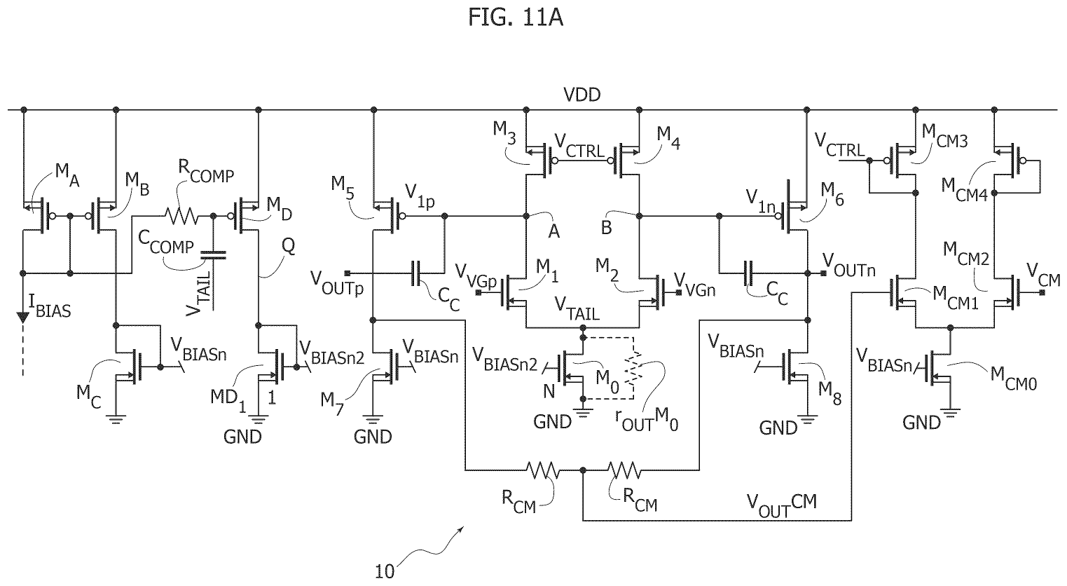

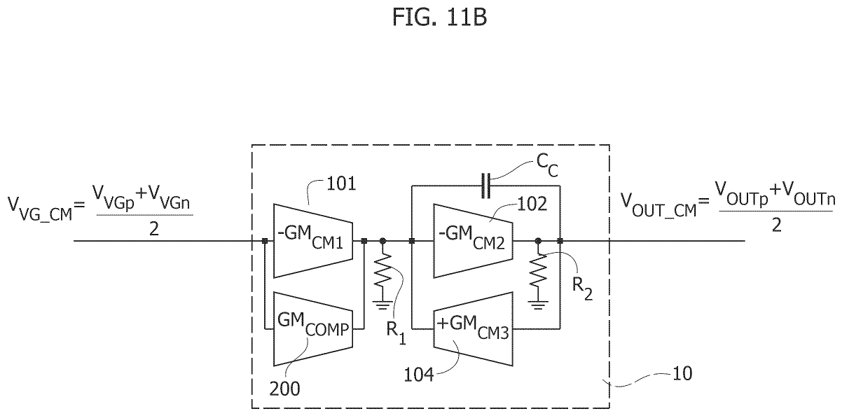

FIG. 10A again recalls a base 2-stage OTA structure showing the possible arrangement of the transistors M_{A}, M_{B}, and M_{C} in combination with conventional OTA circuitry as represented in FIG. 4 (with the C-R network not yet included).

A general concept underlying the solutions of FIGS. 10A, 11A and 12A (and FIG. 9 as well) is the provision of a differential input stage including a first input transistor M₁ and a second input transistor M₂ having control terminals configured to receive a differential input signal V_{Gp}, V_{Gn} applied therebetween as well as a tail transistor M₀.

As illustrated, the first input transistor M₁ has a current flow path therethrough coupled between a common current flow path through the tail transistor M₀ and the (first) node A while the second input transistor M₂ has a current flow path therethrough coupled between the common current flow path through the tail transistor M₀ and the (second) node B.

The solutions of FIGS. 10A, 11A and 12A (and FIG. 9 as well) also include an output stage including a first output transistor M₅ and a second output transistor M₆.

As illustrated, the first output transistor M₅ has a current flow path therethrough between the supply line VDD and a first output node V_{OUTp} that is coupled (via a capacitor C_{C}) to the node A in the differential input stage and the second output transistor M₆ has a current flow path therethrough between the supply line VDD and a second output node V_{OUTn} that is coupled (again via a capacitor C_{C}) to the node B in the differential input stage.

The solutions as illustrated further include common-mode control circuitry comprising a first input transistor M_{CM1} and a second input transistor M_{CM2} having current flow paths therethrough jointly coupled to a ground current flow path through a tail bias transistor M_{CM0}: the first common-mode control transistor M_{CM1} has a control terminal coupled resistively (via the resistors R_{CM}) to the first output node V_{OUTp} and to the second output node V_{OUTn} in the differential output stage.

Additionally, these solutions include a bias generation circuitry that comprises a bias duplicate transistor (this may be any of the transistors M_{C}, M_{D1}, or M_{E}, depending on the embodiment considered) having a current flow path therethrough arranged in a current flow line (this may be through M_{B}, M_{C}, through M_{D}, M_{D1} or through M_{D}, M_{COMP1}, M_{DCOMP2}, M_{E} depending on the embodiment considered) between the supply line VDD and ground GND with the bias duplicate transistor M_{C}, M_{D1} or M_{E} coupled in a (1:N, for instance) current mirror arrangement with the tail transistor M₀ in the differential input stage.

Advantageously, such a differential input stage may include a third (load) transistor M₃ and a fourth (load) transistor M₄.

The current flow path through the first input transistor M₁ may thus be configured to be coupled to the supply line VDD at the node A via a current flow path through the third transistor M₃ with the first input transistor M₁ intermediate the third transistor M₃ and the tail transistor M₀ and the current flow path through the second input transistor (M₂) may be likewise configured to be coupled to the supply line VDD at the node B via a current flow path through the fourth transistor M₄ with the second input transistor M₂ intermediate the fourth transistor M₄ and the tail transistor M₀.

As illustrated, the third transistor M₃ and the fourth transistor M₄ may have control terminals mutually coupled via a control line V_{CTRL}.

Still advantageously, the differential output stage may include a third output (load) transistor (the transistor M₇) with a current flow path therethrough between the first output node V_{OUTp} and ground GND as well as a fourth output (load) transistor (the transistor M₈) with a current flow path therethrough between the second output node V_{OUTn} and ground GND.

As illustrated, the current flow path though the first common-mode control transistor M_{CM1} is configured to be coupled to the supply line VDD via a current flow path through a third common-mode control transistor M_{CM3} having a control terminal coupled to the control line V_{CTRL} between the control terminals of the third transistor M₃ and the fourth transistor M₄ in the differential input stage with the first common-mode control transistor M_{CM1} intermediate the third common-mode control transistor M_{CM3} and the bias tail transistor M_{CM0} and the current flow path through the second common-mode control transistor M_{CM2} configured to be coupled to the supply line VDD via a current flow path through a fourth common-mode control transistor M_{CM4} with the second common-mode control transistor M_{CM2} intermediate the fourth common-mode control transistor M_{CM4} and the common-mode control tail transistor M_{CM0}.

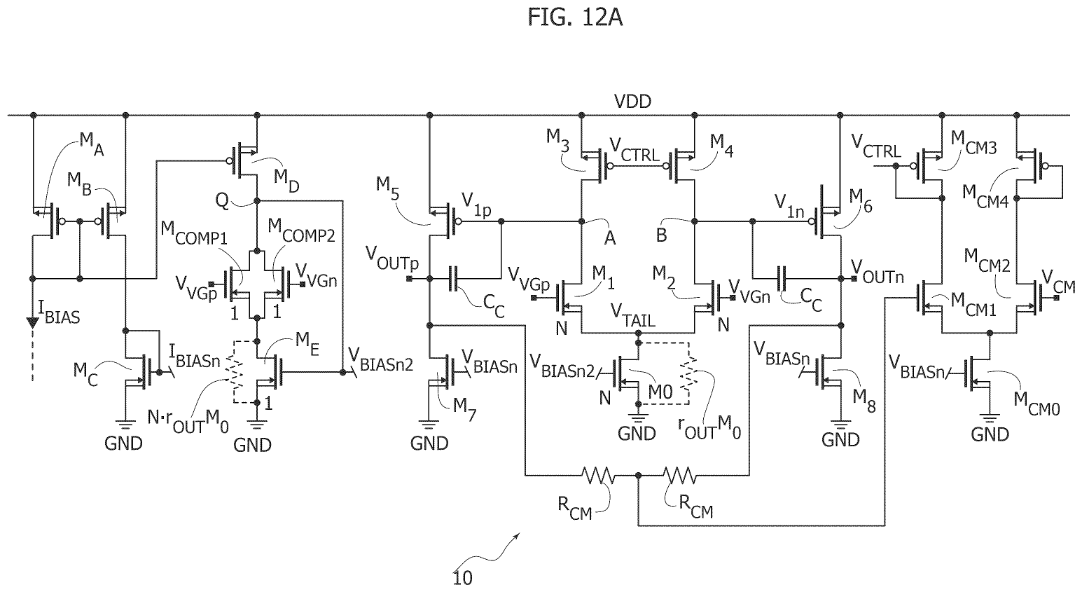

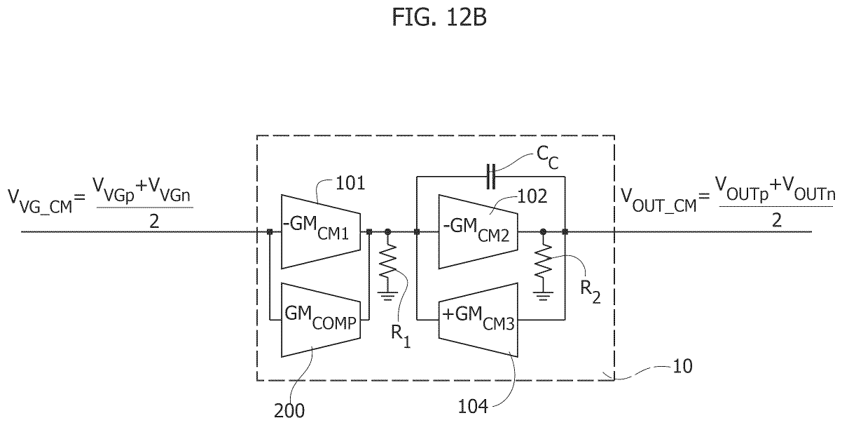

FIGS. 11A and 12A introduce possible circuit implementations of solutions as described herein with and without the C-R network C_{COMP}, R_{COMP} added.

Respective equivalent common-mode models for architectures illustrated in FIGS. 10A, 11A and 12A are reproduced in FIGS. 10B, 11B and 12B.

Throughout FIGS. 10A, 10B, 11A, 11B, 10C, 11C parts/elements/entities already introduced in connection with the previous figures are indicated with the same reference symbols and a detailed description will not be repeated for brevity.

In FIG. 10A, the transistors M_{A} (diode connected) and M_{B} are shown with their gates mutually coupled with the source-drain current flow lines through the transistors M_{B} are M_{C} cascaded in a current flow line between the supply node/line VDD and ground GND. In this case the transistor M_{C} is shown coupled to the tail transistor M₀ in a 1:N current mirror arrangement (the same representation is adopted in FIGS. 10A, 11A, and 12A to indicate the associated form factors, namely “1” and “N”).

In the equivalent common-mode model of FIG. 10B,

$${V}_{GM \_ CM} = ( {V}_{VGp} + {V}_{VGn} ) / 2$$

$${V}_{OUT \_ CM} = ( {V}_{OUTp} + {V}_{OUTn} ) / 2$$

gmMₓ is the transconductance of the transistor Mₓ
rₒᵤₜMₓ is the output resistance of the transistor Mₓ
and

$${GM}_{CM 1} = 1 / 2 {r}_{OUT} {M}_{0}$$

$$R 1 \approx {r}_{OUT} {M}_{3 / 4}$$

$${GM}_{CM 2} = {g}_{m} {M}_{5}$$

$$R 2 = {r}_{OUT} {M}_{5 / 6} \vert \vert {r}_{OUT} {M}_{7 / 8}$$

$${G M}_{CM 3} = {g}_{m} {M}_{C M 1} \cdot {g}_{m} {M}_{3 / 4} / 2 {g}_{m} {M}_{C M 3} .$$

In the implementation of FIG. 11A, the C-R network including the resistor R_{COMP} and the capacitor C_{COMP} (coupled to the “tail” node or line V_{TAIL}) is not coupled between the gates of the transistors M_{A} and M_{B} as exemplified in FIG. 9 but rather between: the mutually coupled gates of the transistors M_{A}, M_{B}, and the gate of a transistor M_{D} having the current flow path therethrough cascaded at a node Q with the current flow path through a transistor M_{D1} in a current flow line between the supply node/line VDD and ground GND.

The control terminal (gate in the case of a field-effect transistor such as a MOSFET transistor) of the transistor M_{D1} has applied thereto a bias voltage V_{BIASn2}.

The voltages V_{BIASn} and V_{BIASn2} have the same DC value, but the node V_{BIASn2} is coupled to the node V_{TAIL} through the capacitance C_{COMP} making the cascade of the transistor M_{D} and M_{D2} a compensation current flow line.

In the equivalent common-mode model of FIG. 11B,

$${V}_{VG \_ CM} = ( {V}_{VGp} + {V}_{VGn} ) / 2$$

$${V}_{OUT \_ CM} = ( {V}_{OUTp} + {V}_{OUTn} ) / 2$$

gmMₓ is the transconductance of the transistor Mₓ
rₒᵤₜMₓ is the output resistance of the transistor Mₓ
C_{g}Mₓ is the gate capacitance of the transistor Mₓ
and

$${GM}_{CM 1} = 1 / 2 {r}_{OUT} {M}_{0}$$

$$R 1 \approx {r}_{OUT} {M}_{3 / 4}$$

$${GM}_{CM 2} = {g}_{m} {M}_{5}$$

$$R 2 = {r}_{OUT} {M}_{5 / 6} \vert \vert {r}_{OUT} {M}_{7 / 8}$$

$${G M}_{CM 3} = {g}_{m} {M}_{C M 1} \cdot {g}_{m} {M}_{3 / 4} / 2 {g}_{m} {M}_{C M 3} .$$

$$Also :$$

$${GM}_{COMP} = {G}_{m} {M}_{D} \cdot {C}_{COMP} / ( {C}_{COMP} + {C}_{g} {M}_{D} ) \cdot N$$

where N is the current mirror factor of the 1:N current mirror arrangement coupling the transistor M_{C} to the tail transistor M₀.

This solution was found to operate adequately for frequencies higher than f_{COM}=1/(2πR_{COMP}·(C_{COMP}+C_{g}M_{D})), namely for a common-mode-feedback bandwidth higher than f_{COMP}.

In the implementation of FIG. 12A (seen in comparison with the implementation of FIG. 11A) the C-R network including the resistor R_{COMP} and the capacitor C_{COMP} is no longer provided and the transistor M_{D1} having the current flow path therethrough cascaded with the current flow path through the transistor M_{D} (having the gate coupled to the mutually coupled gates of the transistors M_{A}, M_{B}) is replaced by the cascaded arrangement (between the node Q and ground GND) of: a complementary transistor pair M_{COMP1}, M_{COMP2}, and a transistor M_{E} having the current path therethrough configured to receive the current from the parallel connection of the current paths through the transistors M_{COMP1}, M_{COMP2} that receive the signals V_{VGp} and V_{VGn} at their control terminals (gates, in the case of field-effect transistors such as MOSFET transistors).

In the implementation of FIG. 12A, the signal V_{BIASn2} is applied both to the node Q between the transistor M_{D} and the transistors M_{COMP1}, M_{COMP2} and to the control terminal (gate, in the case of a field-effect transistor such as a MOSFET transistor) of the transistor M_{E}, which exhibits an output resistance equal to N·rₒᵤₜM₀, where N is the current mirror factor of the 1:N current mirror arrangement coupling the transistor M_{E} to the tail transistor M₀.

In the equivalent common-mode model of FIG. 12B,

$${V}_{VG \_ CM} = ( {V}_{VGp} + {V}_{VGn} ) / 2$$

$${V}_{OUT \_ CM} = ( {V}_{OUTp} + {V}_{OUTn} ) / 2$$

gmMₓ is the transconductance of the transistor Mₓ
rₒᵤₜMₓ is the output resistance of the transistor Mₓ
and

$${GM}_{CM 1} = 1 / 2 {r}_{OUT} {M}_{0}$$

$$R 1 \approx {r}_{OUT} {M}_{3 / 4}$$

$${GM}_{CM 2} = {g}_{m} {M}_{5}$$

$$R 2 = {r}_{OUT} {M}_{5 / 6} \vert \vert {r}_{OUT} {M}_{7 / 8}$$

$${G M}_{CM 3} = {g}_{m} {M}_{C M 1} \cdot {g}_{m} {M}_{3 / 4} / 2 {g}_{m} {M}_{C M 3} .$$

$$Also :$$

$${GM}_{COMP} = N / ( N \cdot {r}_{OUT} {M}_{0} ) = {GM}_{CM 1}$$

The solution of FIG. 12A with the additional stage including the transistors labelled M_{COMP1/2} and M_{E} was found to be effective also for DC conditions.

It is observed that a given current mirror factor/ratio 1:N of the transistors M_{E} and M₀, it is advantageous to preserve the same ratio 1:N between the MOS transistors M_{COMP1/2} and M_{1/2}.

The ratio in question refers to the form factor of the transistors. For instance, N=10 means that M₀ is ten times more conductive than M_{E} (which may be achieved also by including in M₀ ten elementary modules equal to M_{E}).

To summarize, in all of the solutions of FIGS. 10A, 11A and 12A (and FIG. 9 as well) a current flow line (through the transistors M_{B}, M_{C} or through the transistors M_{D}, M_{D1} or through the transistors M_{D}, M_{COMP1}, M_{DCOMP2}, M_{E}) can be provided between the supply line VDD and ground GND that comprises the cascaded connection of the current flow path through the bias duplicate transistor (that is the transistor M_{C}, the transistor M_{D1} or the transistor M_{E}) and the current flow path through a cascaded bias transistor (this may be the transistor M_{B} or the transistor M_{D}, with the parallel connection of the transistors M_{COMP1}, M_{COMP2} possibly in turn cascaded thereto) with such a cascaded bias transistor arranged between the supply line (VDD) and the bias duplicate transistor M_{C}, M_{D1} or M_{E}.

In all of the solutions of FIGS. 10A, 11A and 12A (and FIG. 9 as well) a further bias transistor (namely, the transistor M_{A}) is provided having a flow path therethrough for a bias current I_{BIAS} that is coupled to the supply line VDD and a control terminal coupled to a control terminal of the “cascaded” bias transistor: this may be either the transistor M_{B} (in FIGS. 9 and 10A) of the transistors M_{D} (in FIGS. 11A and 12A).

In the case of FIG. 11A, the control terminal of the further bias transistor M_{A} is coupled both to the control terminal of the cascade bias transistor M_{D} and to a control terminal of another bias transistor M_{B} having a current flow path therethrough cascaded with the current flow path through another bias duplicate transistor M_{C} in a current flow line between the supply line VDD and ground GND.

As exemplified in FIGS. 10A and 12A, the control terminal of the further bias transistor M_{A} is directly coupled to the control terminal of the cascaded bias transistor (namely the transistor M_{B} or the transistor M_{D}).

Conversely, as exemplified in FIGS. 9 and 11A, the control terminal of the further bias transistor M_{A} can be coupled to the control terminal of the cascaded bias transistor (the transistor M_{B} or the transistor M_{D}) via a resistor R_{COMP} in an RC network; such an RC network comprises a capacitor C_{COMP} coupled between the control terminal of the cascaded bias transistor (the transistor M_{B} or the transistor M_{D}) and the common current flow path through the tail transistor M₀.

As exemplified in FIG. 12A, the bias current flow line between the supply line VDD and ground GND comprises a complementary pair of transistors (namely the transistors M_{COMP1} and M_{COMP2}) having current flow paths therethrough arranged in parallel between the current flow path through the bias duplicate transistor (here M_{E}) and the current flow path through the cascaded bias transistor M_{D}; these transistors in the complementary pair M_{COMP1}, M_{COMP2} have control terminals configured to receive applied therebetween the differential input signal V_{Gp}, V_{Gn}.

Once again it is noted that solutions as described herein are suited to operate with “small” supply voltages (supply line VDD) up to 1.1 V, namely 1.1 V or lower.

Advantageously, at least the tail transistor (M₀) in the differential input stage and the bias duplicate transistor (be it any of the transistors M_{C}, M_{D1}, or M_{E}) depending on the embodiments include PMOS transistors.

However, at least some of the field-effect transistors (MOSFET transistors) illustrated herein can be replaced by bipolar junction transistor (BJT), where the control terminals will be the bases of these transistors and the current paths therethrough will be represented by the emitter-collector current flow path.

The figures and the relative description are illustrative of implementations where VDD is assumed to be a positive voltage, with the polarities of the transistors (p-channel/n-channel and p-n-p/n-p-n) selected correspondingly. Those of skill in the art can easily devise corresponding adaptations in case of different voltage/polarity options.

Without prejudice to the underlying principles, the details and embodiments may vary, even significantly, with respect to what has been described by way of example only, without departing from the extent of protection.

The claims are an integral part of the disclosure provided herein in respect of the embodiments.

The extent of protection is determined by the annexed claims.

1. A circuit, comprising:
a differential input stage including a first input transistor, a second input transistor and a tail transistor, wherein the first and second input transistors have control terminals configured to receive a differential input signal applied therebetween, wherein the first input transistor has a current flow path coupled between a current flow path of the tail transistor and a first node, while the second input transistor has a current flow path coupled between the current flow path of the tail transistor and a second node;
a differential output stage including a first output transistor and a second output transistor, wherein the first output transistor has a current flow path between a supply line and a first output node, and wherein a control terminal of the first output transistor is coupled to the first node in the differential input stage; wherein the second output transistor has a current flow path between the supply line and a second output node; and wherein a control terminal of the second output transistor is coupled to the second node in the differential input stage;
common-mode control circuitry comprising a first common-mode control transistor and a second common-mode control transistor having current flow paths jointly coupled to a ground current flow path through a common-mode tail transistor, wherein the first common-mode control transistor has a control terminal resistively coupled to both the first output node and the second output node in the differential output stage; and
bias generation circuitry comprising a bias duplicate transistor having a current flow path arranged in a bias current flow line between the supply line and ground, the bias duplicate transistor coupled in a 1:N current mirror circuit arrangement with the tail transistor in the differential input stage.

2. The circuit of claim 1, wherein the differential input stage includes a third input transistor and a fourth input transistor, wherein the current flow path through the first input transistor is configured to be coupled to the supply line at the first node via a current flow path of the third input transistor with the first input transistor intermediate the third input transistor and the tail transistor, wherein the current flow path of the second input transistor is configured to be coupled to the supply line at the second node via a current flow path of the fourth input transistor with the second input transistor intermediate the fourth input transistor and the tail transistor, and wherein the third input transistor and the fourth input transistor have control terminals mutually coupled via a control line.

3. The circuit of claim 2, wherein the differential output stage includes: a third output transistor with a current flow path between the first output node and ground; and a fourth output transistor with a current flow path between the second output node and ground.

4. The circuit of claim 2, wherein the current flow path of the first common-mode control transistor is configured to be coupled to the supply line via a current flow path of a diode-connected third common-mode control transistor having a control terminal coupled to the control line between the control terminals of the third input transistor and the fourth input transistor in the differential input stage with the first common-mode control transistor intermediate the third common-mode control transistor and the common-mode tail transistor, and wherein the current flow path of the second common-mode control transistor is configured to be coupled to the supply line via a current flow path of a diode-connected fourth common-mode control transistor with the second common-mode control transistor intermediate the fourth common-mode control transistor and the common-mode tail transistor.

5. The circuit of claim 1, wherein the bias current flow line between the supply line and ground comprises a cascaded connection of the current flow path of the bias duplicate transistor and the current flow path of a cascaded bias transistor with the cascaded bias transistor between the supply line and the bias duplicate transistor.

6. The circuit of claim 5, further comprising a further bias transistor having a bias current flow path coupled to the supply line and a control terminal coupled to a control terminal of the cascaded bias transistor.

7. The circuit of claim 6, wherein the control terminal of the further bias transistor is coupled both to the control terminal of the cascaded bias transistor and to a control terminal of another bias transistor having a current flow path cascaded with the current flow path of another bias duplicate transistor in a current flow line between the supply line and ground.

8. The circuit of claim 7, wherein the control terminal of the further bias transistor is directly coupled to the control terminal of the cascaded bias transistor.

9. The circuit of claim 5, wherein the bias current flow line between the supply line and ground comprises a complementary pair of transistors having current flow paths arranged in parallel between the current flow path of the bias duplicate transistor and the current flow path of the cascaded bias transistor, and wherein the transistors in the complementary pair of transistors have control terminals configured to receive said differential input signal applied therebetween.

10. The circuit of claim 9, wherein:
the bias duplicate transistor and the tail transistor in the differential input stage have 1:N current mirror ratios therebetween; and
the transistors in said complementary pair of transistors and the first input transistor and the second input transistor in the differential input stage have 1:N current mirror ratios therebetween.

11. The circuit of claim 6, wherein the control terminal of the further bias transistor is coupled to the control terminal of the cascaded bias transistor via a resistor in a resistor capacitor (RC) network, the RC network comprising a capacitor coupled between the control terminal of the cascaded bias transistor and the common current flow path of the tail transistor.

12. The circuit of claim 1, wherein said supply line is configured to receive a supply voltage up to 1.1 V.

13. The circuit of claim 1, wherein the tail transistor in the differential input stage and said bias duplicate transistor are PMOS transistors.

14. A device including the circuit according to claim 1, wherein the device comprises a capacitive sensor.

15. A method, comprising:
applying a differential input signal across the control terminals a first input transistor and a second input transistor in a differential input stage of an amplifier including a tail transistor, wherein the first input transistor has a current flow path coupled between a current flow path of the tail transistor and a first node and wherein the second input transistor has a current flow path coupled between the current flow path through the tail transistor and a second node;
providing in said amplifier a differential output stage including a first output transistor and a second output transistor, wherein the first output transistor has a current flow path between a supply line and a first output node that is coupled to the first node in the differential input stage and wherein the second output transistor has a current flow path between the supply line and a second output node that is coupled to the second node in the differential input stage;
controlling common-mode operation of the amplifier via a first common-mode control transistor and a second common-mode control transistor having current flow paths jointly coupled to a ground current flow path through a common-mode tail transistor by resistively coupling the control terminal of the first common-mode control transistor to the first output node and the second output node in the differential output stage;
providing bias generation circuitry comprising a bias duplicate transistor having a current flow path arranged in a bias current flow line between the supply line and ground; and
coupling the bias duplicate transistor in a 1:N current mirror arrangement with the tail transistor in the differential input stage.

16. The method of claim 15, further comprising coupling the control terminal of the further bias transistor to the control terminal of the cascaded bias transistor via a resistor in a resistor capacitor (RC) network, the RC network comprising a capacitor coupled between the control terminal of the cascaded bias transistor and the common current flow path of the tail transistor.
